(19) United States
(12) Patent Application Publication
(10) Pub. No.: US 2008/0315307 A1
(43) Pub. Date: Dec. 25, 2008

(54) HIGH VOLTAGE DEVICE

(75) Inventors: Cheng Yu FANG, Hsinchu City (TW); Sheng Yuan Yang, Sanchong City (TW); Wei Jung Chen, Hsinchu (TW)

Correspondence Address: EGBERT LAW OFFICES, 412 MAIN STREET, 7TH FLOOR, HOUSTON, TX, 77002, US

(73) Assignee: ADVANCED ANALOG TECHNOLOGY, Inc., Hsinchu (TW)

(21) Appl. No.: 12/204,339

(22) Filed: Sep. 4, 2008

Related U.S. Application Data
(62) Division of application No. 11/621,517, filed on Jan. 9, 2007.

(30) Foreign Application Priority Data
Aug. 30, 2006 (TW) 095131949

(51) Int. Cl. H01L 29/78

(52) U.S. Cl. 257/341; 257/E29.256

(57) ABSTRACT

A high voltage device includes a semiconductor substrate and a gate. The semiconductor substrate includes a first doped region having a first conductive type, a second doped region having a second conductive type, a third doped region having the second conductive type, a fourth doped region surrounding the third doped region and having the second conductive type, and a fifth doped region surrounding the third doped region and having the second conductive type. The gate is disposed between two spacers to separate the second doped region from the third doped region, so as to control the conduction of the second doped region and the third doped region. In the high voltage device, the fifth doped region surrounds the third doped region, so as to strengthen the coverage for the third doped region and improve the ion concentration uniformity on the bottom of the third doped region to reduce leakage current.

### CROSS-REFERENCE TO RELATED APPLICATIONS

The present application is a divisional application under 35 U.S.C. §121 of U.S. application Ser. No. 11/621,517, filed on Jan. 9, 2007 and entitled “HIGH VOLTAGE DEVICE AND MANUFACTURING METHOD THEREOF”, presently pending.

### STATEMENT REGARDING FEDERALLY SPONSORED RESEARCH OR DEVELOPMENT

Not applicable.

### NAMES OF THE PARTIES TO A JOINT RESEARCH AGREEMENT

Not applicable.

### INCORPORATION-BY-REFERENCE OF MATERIALS SUBMITTED ON A COMPACT DISC

Not applicable.

### BACKGROUND OF THE INVENTION

1. Field of the Invention

The present invention relates to a high voltage device and a manufacturing method thereof, and more particularly to a high voltage metal-oxide-semiconductor transistor (HVMOS transistor) and a manufacturing method thereof, wherein the HVMOS transistor is particularly suitable for an electrostatic discharge (ESD) protection circuit.

2. Description of Related Art Including Information Disclosed Under 37 CFR 1.97 and 37 CFR 1.98.

The problem of ESD often occurs when manufacturing and using an integrated circuit (IC). When the demand for high-speed operation and integrated circuits used in wireless broadband communication products increases and the IC process rapidly enters the era of 80 nanometers, even below 65 nanometers, the components inside the IC are very tiny and may be easily damaged by instant ESD. Therefore, ESD will greatly affect the quality of the IC, and the problems caused by ESD become increasingly severe as the IC process becomes more and more accurate.

FIG. 1 shows a conventional ESD protection circuit 3. The ESD protection circuit 3 is disposed between an internal circuit 31 to be protected and a bonding pad 32, and the bonding pad 32 is connected to an I/O pin (not shown) for a subsequent packaging process. The ESD protection circuit 3 includes an input terminal 36, a voltage source (for example, 30V) 37, a ground terminal 38, a first high voltage N-type MOS (HVNMOS) transistor 34, a second HVNMOS transistor 35, and a high voltage P-type MOS (HVPMOS) transistor 33. The input terminal 36 is electrically connected to the bonding pad 32 and the internal circuit 31. The first HVNMOS transistor 34 is disposed between the input terminal 36 and the ground terminal 38. The HVPMOS transistor 33 is disposed between the voltage source 37 and the input terminal 36. The second HVNMOS transistor 35 is disposed between the voltage source 37 and the ground terminal 38 and is electrically connected to the HVPMOS transistor 33. With regard to the HVMOS transistors 33, 34, or 35, the source, body and drain form a parasitic bipolar junction transistor. The threshold voltage of the parasitic bipolar junction transistor is less than a breakdown voltage of the gate in the internal circuit 31. Therefore, before the ESD pulse (i.e., the generation of ESD) enters the internal circuit 31, the parasitic bipolar junction transistor is firstly turned on to prevent an excessive voltage or a current surge from damaging the internal circuit 31. An input voltage from the bonding pad 32 enters the internal circuit 31 through the input terminal 36 of the ESD protection circuit 3. When the input voltage is larger than the threshold voltage of the parasitic bipolar junction transistor disposed in the HVPMOS transistor 33 and the HVNMOS transistors 34 and 35, the transistors 33, 34, and 35 are turned on and a big current caused by the input voltage is conducted to the ground terminal 38, thereby eliminating the high voltage generated at the input terminal 36.

FIG. 2 is a schematic sectional view of the structure of an HVNMOS transistor 1 applied in the ESD protection circuit 3 in FIG. 1. The HVNMOS transistor 1 includes a semiconductor substrate 16, a P-type well 15 disposed on the semiconductor substrate 16, a gate 10 disposed on the surface of the P-type well 15, two spacers 11 closely adjacent to the two sides of the gate 10, a heavily doped source 12, a heavily doped drain 13, and a lightly doped drain 14 surrounding the heavily doped drain 13. In this embodiment, the lightly doped drain 14 is an N-type doped drain (NDD). The heavily doped drain 13 and the lightly doped drain 14 form a double diffusion drain. The double diffusion drain is designed to increase a breakdown voltage of the HVNMOS transistor 1 and solve the problem of hot carrier. However, the HVMOS transistor shown in FIG. 2 has the problem of a leakage current, as shown in FIGS. 3(a) and 3(b). FIG. 3(a) is a characteristic curve chart of Ids and VDS (the potential difference between the source and the drain) when the HVNMOS transistor 1 in FIG. 2 is under different gate voltages (VG), wherein the curves A1-A7 are Ids-VDS characteristic curves when the gate voltages are 0 V, 2 V, 4 V, 6 V, 8 V, 10 V, and 12 V, respectively. FIG. 3(b) is a characteristic curve diagram of the substrate current Isub and the gate voltage (VG) when the HVNMOS transistor 1 is under different VDS, wherein the curves B1-B6 are I_{sub}-VG characteristic curves when the VDS is 0 V, 16 V, 17 V, 18 V, 19 V, and 20 V, respectively. It can be known from FIG. 3(a) that when VDS is larger than 12 V and the gate voltage VG is larger than 10 V, Ids is obviously increased. Furthermore, it can be known from FIG. 3(b) that when VDS is larger than 16 V and the gate voltage VG is larger than 10 V, the substrate current Isub is obviously increased. It should be noted that the data in FIGS. 3(a) and 3(b) is measured by using the HVMOS transistor with a gate length of 1.8 μm and a width of 50 μm. Additionally, referring to the curve F in FIG. 7, which is a characteristic curve of the substrate current Isub and VDS when the HVNMOS transistor 1 in FIG. 2 is turned off (VG=0 V), the curve F indicates that although the HVNMOS transistor 1 is turned off (VG=0 V), when VDS is larger than 12 V, the substrate current Isub is obviously increased. The problems of the leakage current in FIGS. 3(a) and 3(b) are caused due to the following facts. When the double diffusion drain in FIG. 2 is formed, the implantation energy and dosage used to form the heavily doped drain 13 are both larger that those used to form the lightly doped drain 14, and are diffused strongly during a thermal annealing process, thus resulting in a non-uniform ion concentration on the bottom NB (see FIG. 2) of the heavily doped drain 13. That is to say, the coverage of the lightly doped drain 14 on the bottom NB is not preferred and thus the following circumstances will occur when VDS received by the HVNMOS transistor 1 is larger than 12 V. (1) Hot carrier effect causes a high substrate current Isub, thus resulting in a leakage current (see FIGS. 3(a) and 3(b)); (2) even though the HVNMOS transistor 1 is turned off, an obvious leakage current occurs at the drain (see the curve F in FIG. 7). Since the uniformity of the ion concentration on the bottom NB is not preferred, when the HVNMOS transistor 1 is used in the ESD protection circuit, and an ESD pulse occurs, the bottom NB is firstly damaged, and then the ESD protection circuit loses effectiveness.

### BRIEF SUMMARY OF THE INVENTION

The present invention is directed to providing a high voltage device. A fifth lightly doped region with a second conductive type is further used to surround a third heavily doped region with the second conductive type, so as to intensify the coverage for the third doped region. Thus, the ion concentration uniformity on the bottom of the third doped region is improved to reduce a leakage current.

The present invention is further directed to providing a method of manufacturing a high voltage device. A photomask originally for defining a well region is used to define the well region and a fifth doped region simultaneously. The fifth doped region is used to surround a third heavily doped region which is formed later, so as to intensify the coverage of the third doped region. Thus, the ion concentration uniformity on the bottom of the third doped region is improved to reduce a leakage current.

The present invention provides a high voltage device, which includes a semiconductor substrate and a gate. The semiconductor substrate includes a first doped region with a first conductive type, a second doped region with a second conductive type, a third doped region with the second conductive type, a fourth doped region with the second conductive type, and a fifth doped region with the second conductive type. The fifth doped region is partially overlapped by the fourth doped region, wherein the overlapped region surrounds the third doped region. Two spacers are disposed on both sides of the gate and also disposed on the surface of the semiconductor substrate between the second doped region and the third doped region, for controlling the conductivity between the second doped region and the third doped region.

The high voltage device may be manufactured by (1) forming a first doped region with a first conductive type on a semiconductor substrate; (2) forming a fifth doped region with a second conductive type in the first doped region; (3) forming a gate and two spacers disposed on both sides of the gate on the surface of the first doped region; (4) forming a fourth doped region with the second conductive type; and (5) forming a second doped region with the second conductive type and a third doped region having the second conductive type, wherein the third doped region is surrounded by the fourth doped region and the fifth doped region.

In the present invention, a photomask originally for defining a well region is used to define the well region and the fifth doped region simultaneously, wherein the third doped region is surrounded by the fifth doped region, such that the high voltage device provided by the present invention may effectively reduce the leakage current without increasing cost and steps of process, so as to improve the performance of the ESD protection circuit efficiently. Furthermore, the fifth doped region does not surround the sides of the fourth doped region, i.e., does not cover the interfacial region between the fourth doped region and the bottom of the adjacent gate, and thus the original electrical characteristics of the high voltage device are not affected.

### BRIEF DESCRIPTION OF THE SEVERAL VIEWS OF THE DRAWINGS

The invention will be described according to the appended drawings.

FIG. 1 shows a schematic view of a conventional ESD protection circuit.

FIG. 2 is a schematic sectional view of the structure of the HVNMOS transistor applied in the ESD protection circuit in FIG. 1.

FIG. 3(a) is a characteristic curve diagram of Ids and VDS of the HVNMOS transistor in FIG. 2.

FIG. 3(b) is a characteristic curve diagram of the substrate current Isub and the gate voltage VG of the HVNMOS transistor in FIG. 2.

FIG. 4 is a schematic sectional view of the structure of the high voltage device according to the present invention.

FIGS. 5(a)-5(d) are schematic views of manufacturing the high voltage device according to the present invention.

FIG. 6(a) is a characteristic curve diagram of Ids and VDS of the high voltage device according to the present invention.

FIG. 6(b) is a characteristic curve diagram of the substrate current Isub and the gate voltage VG of the high voltage device according to the present invention.

FIG. 7 is a characteristic curve diagram of the substrate current and VDS when the high voltage device is turned off.

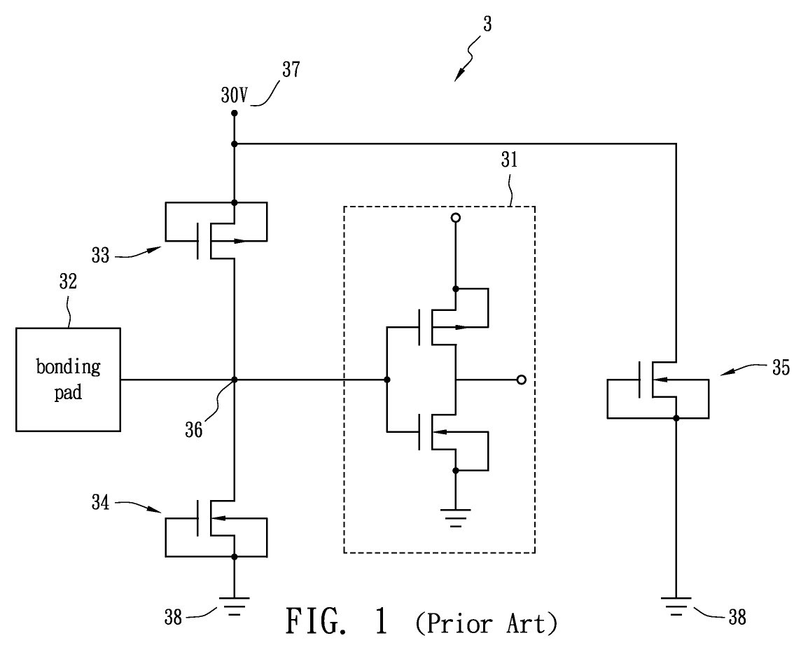

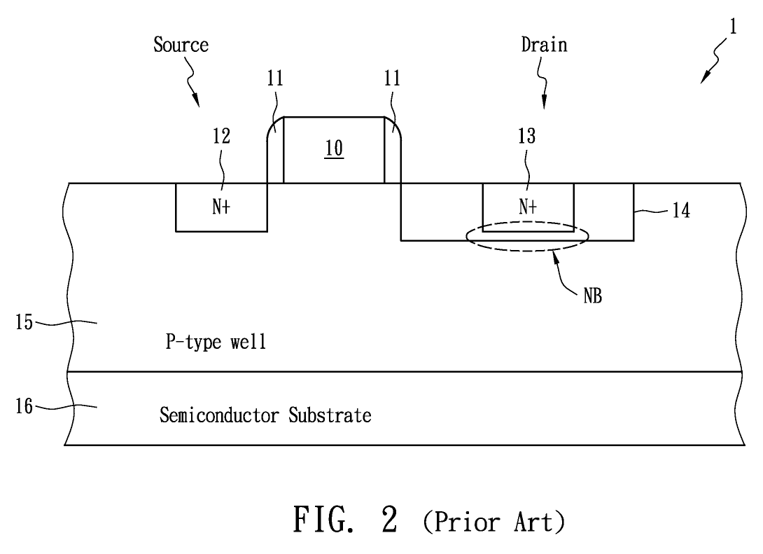

### DETAILED DESCRIPTION OF THE INVENTION

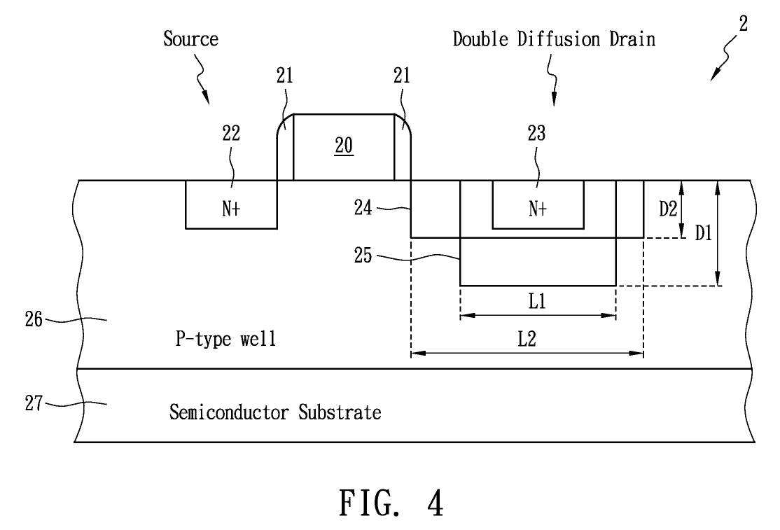

FIG. 4 is a schematic sectional view of the structure of the high voltage device 2 according to the present invention. The high voltage device 2 includes a semiconductor substrate 27 and a gate 20 closely disposed between two spacers 21. The semiconductor substrate 27 includes a P-type well region 26, an N-type second doped region 22, an N-type third doped region 23, an N-type fourth doped region 24 surrounding the N-type third doped region 23, and an N-type fifth doped region 25 surrounding the N-type third doped region 23. The gate 20 is used to control the conduction between the N-type second doped region 22 and the N-type third doped region 23. The length L2 of the N-type fourth doped region 24 is larger than the length LI of the N-type fifth doped region 25, and the depth D1 of the N-type fifth doped region 25 is larger than the depth D2 of the N-type fourth doped region 24. Therefore, the N-type fifth doped region 25 completely covers the N-type third doped region 23, but does not cover the interfacial region of the N-type fourth doped region 24 and the bottom of the adjacent gate 20. Furthermore, the N-type third doped region 23 and the N-type fourth doped region 24 form a double diffusion drain.

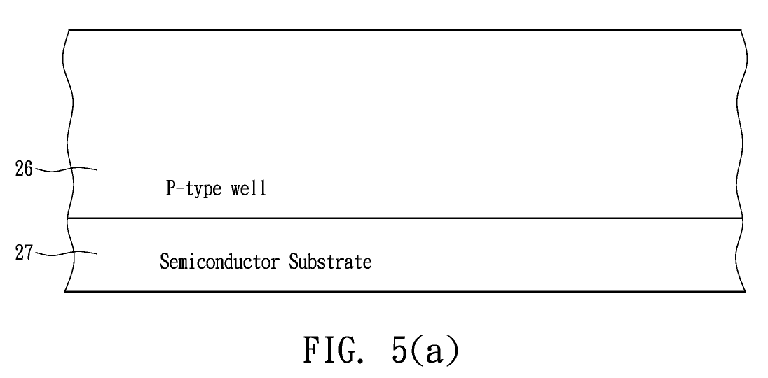

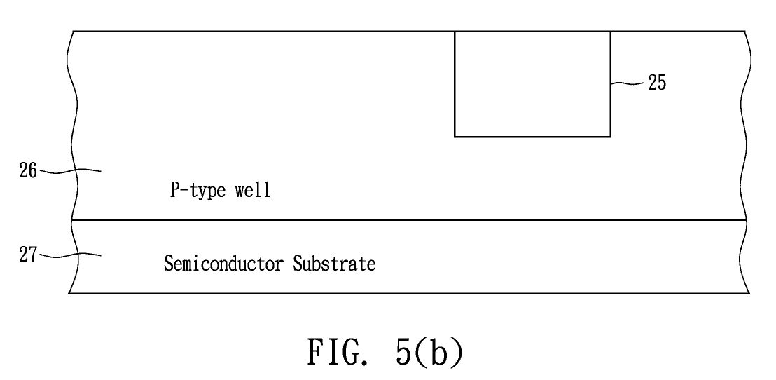

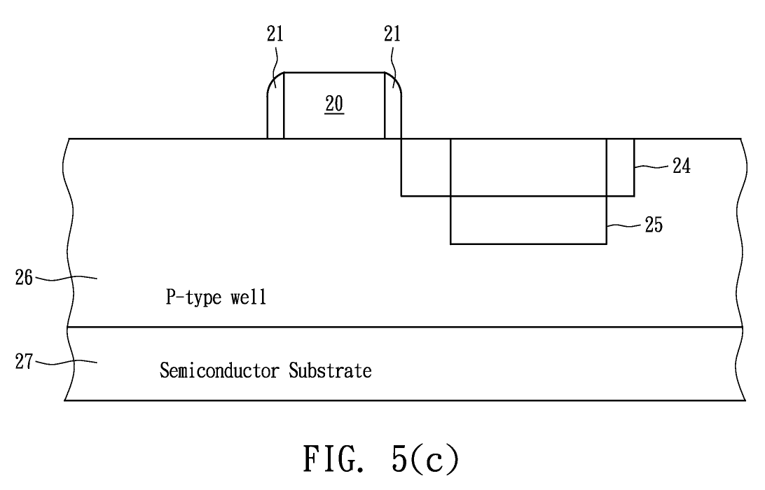

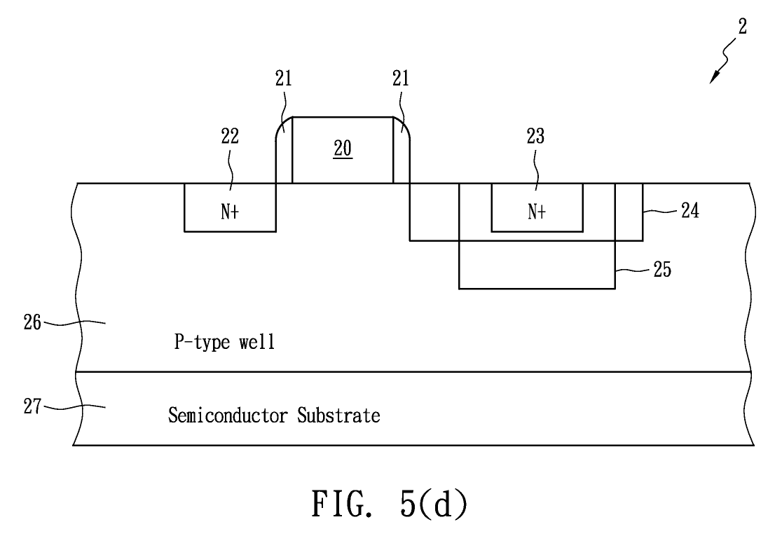

FIGS. 5(a)-5(d) are schematic views of the flow of manufacturing the high voltage device 2 in FIG. 4 according to the present invention. Firstly, a P-type well region 26 is formed on the semiconductor substrate 27, as shown in FIG. 5(a). Then, an N-type fifth doped region 25 is formed in the P-type well region 26, as shown in FIG. 5(b). A predetermined ion implantation region for the N-type fifth doped region 25 is defined by a photomask, and then an ion implantation process and a thermal diffusion process are performed, thereby forming the N-type fifth doped region 25. Next, the gate 20 and two spacers disposed on both sides of the gate 20 are formed on the surface of the P-type well region 26. After that, the N-type fourth doped region 24 is formed through a self-aligned process by using the gate 20 and the spacers 21 as an ion implant mask, as shown in FIG. 5(C). The N-type fourth doped region 24 and the N-type fifth doped region 25 have the same doping concentration. Thereafter, the N-type second doped region 22 and the N-type third doped region 23 are formed through another doping process, as shown in FIG. 5(d). The N-type second doped region 22 and the N-type third doped region 23 have the same doping concentration (about 10¹⁵/cm²), which is larger than the doping concentration (10¹²/cm²) of the N-type fourth doped region 24. As for the method of forming the high voltage device of the present invention, the step of forming the N-type fifth doped region 25 is before the step of forming the gate 20, as shown in FIGS. 5(b) and 5(c); therefore, the channel of the gate 20 is efficiently controlled to achieve the electrical characteristics predetermined when designing the high voltage device 2.

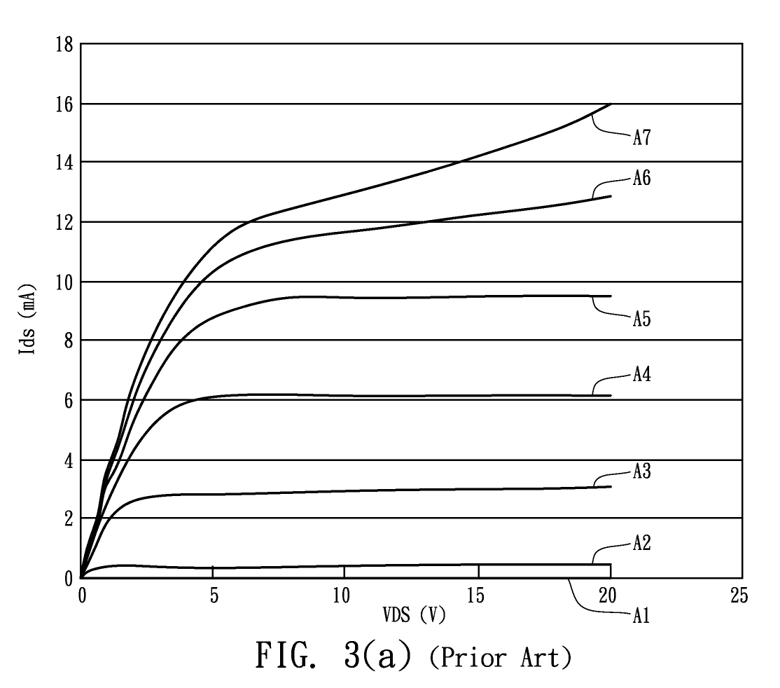

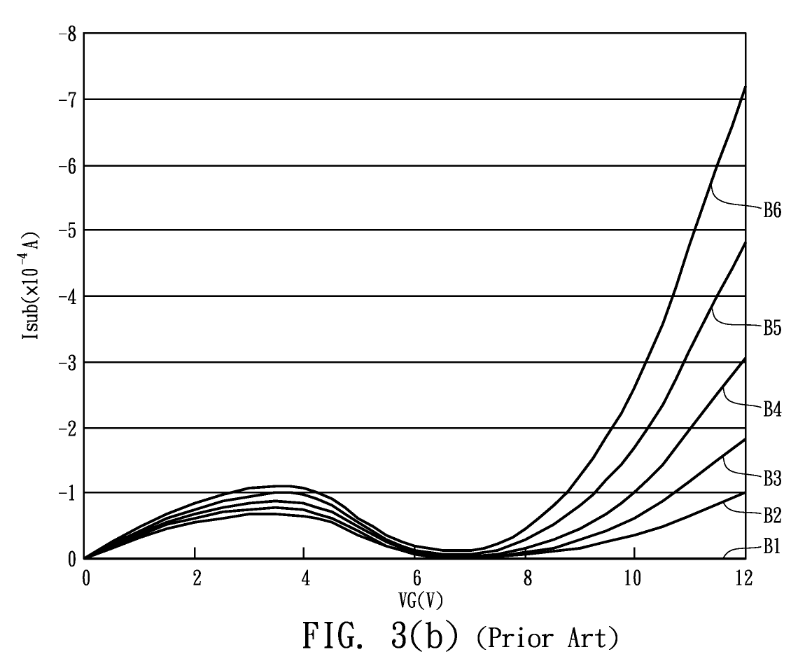

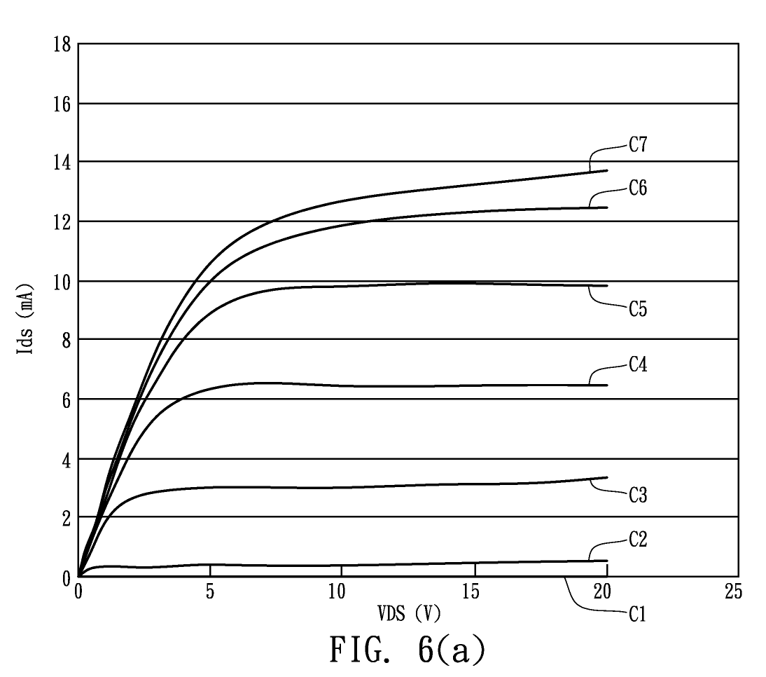

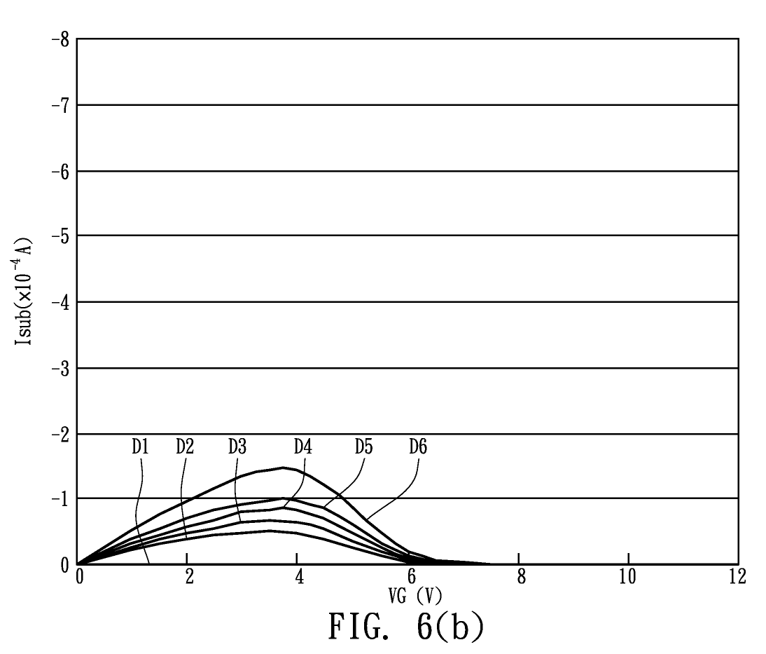

FIG. 6(a) is a characteristic curve diagram of Ids and VDS of the high voltage device 2 according to the present invention under different gate voltages (VG), wherein the curves C1-C7 are I_{ds}-VDS characteristic curves when the gate voltage (VG) is 0 V, 2 V, 4 V, 6 V, 8 V, 10 V, and 12 V, respectively. Compared with FIG. 3(a), it can be known that I_{ds} in the curves C6 and C7 in FIG. 6(a) is not obviously increased when VDS is larger than 12 V. FIG. 6(b) is a characteristic curve diagram of the substrate current I_{sub} and the gate voltage (VG) of the high voltage device 2 in FIG. 4 under different VDS, wherein the curves D1-D6 are I_{sub}-VG characteristic curves when the VDS is 0 V, 16 V, 17 V, 18 V, 19 V, and 20 V, respectively. Compared with the curves B1-B6 in FIG. 3(b), the curves D1-D6 in FIG. 6(b) only have one hump, i.e., no substrate current I_{sub} is generated after VG is larger than 7 V. It should be noted that the data in FIGS. 6(a) and 6(b) is measured by using a HVMOS transistor having a gate length of 1.8 μm and a gate width of 50 μm.

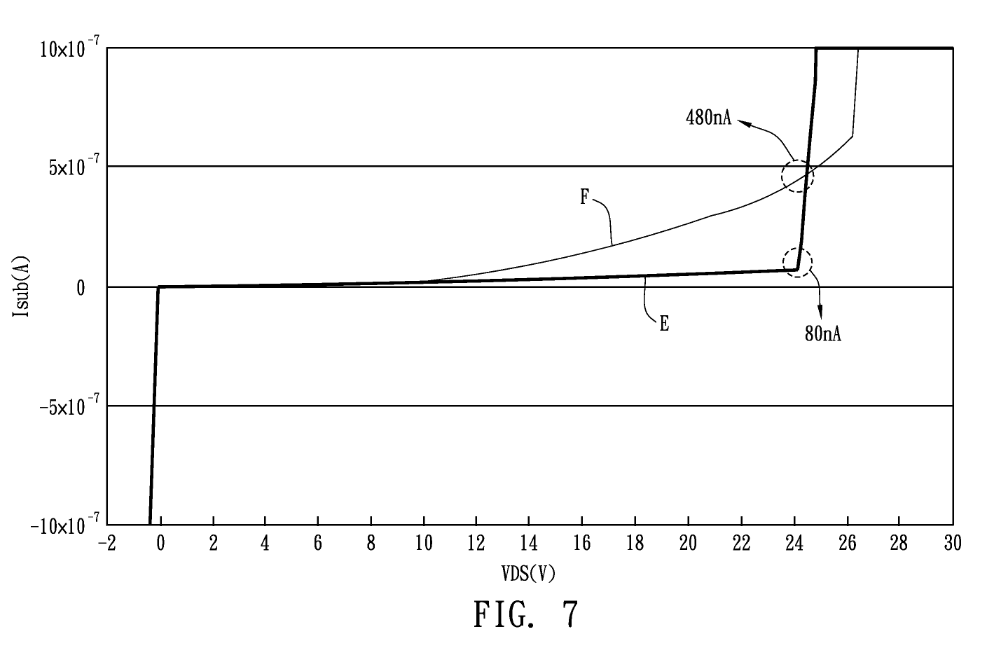

FIG. 7 is a characteristic curve diagram of the substrate current I_{sub} and VDS when the high voltage device is turned off (VG=0 V), wherein the curves E and F represent the characteristic curves of the substrate current I_{sub} and VDS of the high voltage device 2 of the present invention and the conventional HVNMOS transistor 1, respectively. It can be known from FIG. 7 that when the high voltage device of the present invention is under VDS larger than 12 V, it nearly causes the substrate current I_{sub} not to increase. Even though VDS is increased to be 24 V, the substrate current I_{sub} is merely increased to be 80 nA. However, when the conventional HVNMOS transistor 1 is under VDS larger than 12 V, the substrate current I_{sub} is obviously increased, and when VDS is increased to be 24 V, the substrate current I_{sub} is greatly increased to 480 nA.

In view of the above, compared with the conventional high voltage device, the high voltage device provided by the present invention has the following advantages. When being turned off (VG=0 V), the high voltage device may bear high VDS and generate a tiny leakage current (or substrate current), and the substrate current does not cause double hump, as shown in FIGS. 3(b) and 6(b). Under high voltage operation (VG is larger than 8 V), the high voltage device does not cause a high substrate current and has a flat saturation current I_{ds}, as shown in FIGS. 3(a) and 6(a). It is mainly because the fifth doped region in the present invention has a preferred coverage on the third doped region, and at the same time, the ion concentration uniformity on the bottom of the third doped region is improved, thus reducing the leakage current efficiently. Furthermore, the method of manufacturing the high voltage device of the present invention does not involve any additional processes or steps and does not increase the number of the photomasks, so as not to increase the cost. Due to the aforementioned advantages of the present invention, when designing the high voltage device, the gate width may be reduced to further reduce the area thereof, and at the same time, the operational voltage and current are increased.

The above-described embodiments of the present invention are intended to be illustrative only. Numerous alternative embodiments may be devised by those skilled in the art without departing from the scope of the following claims.

We claim:

1. A high voltage device, comprising:
a semiconductor substrate, comprising:
a first doped region with a first conductive type;
a second doped region with a second conductive type;
a third doped region with the second conductive type;
a fourth doped region with the second conductive type; and
a fifth doped region with the second conductive type and being partially overlapped by the fourth doped region, wherein the overlapped region surrounds the third doped region; and
a gate disposed on the surface of the semiconductor substrate between the second doped region and the third doped region so as to control the conductivity between the second doped region and the third doped region.

2. The high voltage device of claim 1, wherein the length of the fourth doped region is larger than the length of the fifth doped region.

3. The high voltage device of claim 1, wherein the depth of the fifth doped region is larger than the depth of the fourth doped region.

4. The high voltage device of claim 1, wherein the third and fourth doped regions form a double diffusion drain.

5. The high voltage device of claim 1, wherein the fourth and fifth doped regions have the same doping concentration.

6. The high voltage device of claim 1, wherein the second and third doped regions have the same doping concentration.

7. The high voltage device of claim 1, wherein the doping concentration is larger for the third doped region than for the fourth doped region.
